(19) United States
(12) Patent Application Publication
(10) Pub. No.: US 2026/0150274 A1
(43) Pub. Date: May 28, 2026

(54) SEMICONDUCTOR DEVICES AND FABRICATION METHODS THEREOF

(71) Applicant: Yangtze Memory Technologies Co., Ltd., Wuhan (CN)

(72) Inventors: Zongliang Huo, Wuhan (CN); Wei Xu, Wuhan (CN); Longxiang Yan, Wuhan (CN); Qiangwei Zhang, Wuhan (CN); Bin Yuan, Wuhan (CN)

(21) Appl. No.: 19/016,955

(22) Filed: Jan. 10, 2025

(30) Foreign Application Priority Data
Nov. 27, 2024 (WO) PCT/CN2024/134870
Nov. 28, 2024 (CN) 202411735062.7

(51) Int. Cl. H10B 12/00; G11C 5/06

(52) U.S. Cl. CPC H10B 12/50; G11C 5/063; H10B 12/03; H10B 12/488

(57) ABSTRACT

Some implementations of memory devices and fabrication method of the memory devices are provided. One of the memory devices includes an array of memory cells in a memory array area and a plurality of word lines extending, in a first direction, from the memory array area to a connection area. Each memory cell includes a semiconductor body. In the connection area, word-line interconnects extend in a third direction to connect with the plurality of word lines. The plurality of word lines include a first word line and a second word line arranged in a second direction and between two rows of the semiconductor bodies. In the second direction, a first distance between the first word line and the second word line in the connection area is greater than a second distance between the first word line and second word line in the memory array area.

### CROSS-REFERENCE TO RELATED APPLICATIONS

This application claims the benefit of priorities to International Application No. PCT/CN 2024/134870, filed on Nov. 27, 2024, and Chinese Application No. 202411735062.7, filed on Nov. 29, 2024, both of which are incorporated herein by reference in their entireties.

### BACKGROUND

The present disclosure generally relates to the field of semiconductor technology, and more particularly, to semiconductor devices and fabrication methods thereof.

Planar memory cells have traditionally been scaled down by advancements in process technology, circuit design, programming algorithms, and fabrication techniques. However, as the feature sizes of these memory cells approach their physical limits, continuing with planar processes becomes increasingly challenging and expensive. Consequently, the memory density achievable with planar memory cells is nearing its maximum capacity.

To overcome these density limitations, three-dimensional (3D) memory architectures have been introduced. The innovative approach of a 3D memory architecture offers a promising solution, enabling higher memory density and addressing the inherent constraints of planar memory cells.

### SUMMARY

Some implementations of 3D memory devices and methods for forming the same are disclosed herein.

In certain aspects, one of the memory devices is provided. The memory device may include an array of memory cells in a memory array area and a plurality of word lines extending, in a first direction, from the memory array area to a connection area. The memory cell may include a semiconductor body. In the connection area, word-line interconnects may extend in a third direction to connect with the plurality of word lines. The plurality of word lines may include a first word line and a second word line arranged in a second direction and between two rows of the semiconductor bodies. In the second direction, a first distance between the first word line and the second word line in the connection area may be greater than a second distance between the first word line and second word line in the memory array area.

In some implementations, in the third direction, one word-line interconnect of the word-line interconnects may extend through a first dielectric layer and a second dielectric layer of a stack structure in the connection area to connect with a corresponding word line of the plurality of word lines. The first dielectric layer may be different from the second dielectric layer.

In some implementations, one of the memory cells may further include a storage unit. A third dielectric layer may be arranged laterally and approximately at a level, relative to the third direction, where an electrode structure of the storage unit may be connected with a corresponding semiconductor body of the semiconductor bodies.

In some implementations, the third dielectric layer may include a silicon boron nitride layer.

In some implementations, the third dielectric layer may extend across the memory array area, without extending to the connection area.

In some implementations, one memory cell of the array of memory cells may include a storage unit that includes an electrode structure having a first end connected with one semiconductor body of the semiconductor bodies and a second end. One word-line interconnect of the word-line interconnects may include a third end connected with the first word line and a fourth end. The second end of the electrode structure may be substantially flush with the fourth end of the word-line interconnect.

In some implementations, a surface area of the second end of the electrode structure may be substantially identical to a surface area of the fourth end of the word-line interconnect.

In some implementations, in the third direction, a length of the word-line interconnect may be greater than a length of the electrode structure of the storage unit.

In some implementations, the memory array area may include a first sub-memory area and a second sub-memory area. One word line of the plurality of word lines may extend, in the first direction, from the first sub-memory area to the second sub-memory area. The connection area may be arranged between the first sub-memory area and the second sub-memory area.

In some implementations, the two rows of the semiconductor bodies may include a first row of the semiconductor bodies and a second row of the semiconductor bodies. The memory device may further include an isolation structure arranged between the second row of the semiconductor bodies and a third row of the semiconductor bodies and configured to isolate the second row of the semiconductor bodies from the third row of the semiconductor bodies.

In some implementations, in the second direction, a first end of the first word line may be substantially flush with a second end of the second word line.

In some implementations, a first semiconductor structure may include the array of memory cells and the plurality of word lines. The memory device may further include peripheral circuits arranged in a second semiconductor structure. The first semiconductor structure may be bonded with the second semiconductor structure. The plurality of word lines in the first semiconductor structure may be electrically coupled with the peripheral circuits of the second semiconductor structure.

In certain aspects, another memory device is provided. The memory device may include an array of memory cells in a memory array area. The memory cell may include a semiconductor body. A plurality of word lines may extend, in a first direction, from the memory array area to a connection area. In the connection area, word-line interconnects may extend in a third direction to connect with the plurality of word lines. The third direction may be perpendicular to the first direction. The plurality of word lines may include a first word line and a second word line arranged in a second direction and between two rows of the semiconductor bodies. The second direction may be perpendicular to the first and third directions. In the second direction, a first distance between the first word line and the second word line in the connection area may be different from a second distance between the first word line and second word line in the memory array area. A first end of the first word line may be substantially flush with a second end of the second word line in the second direction.

In some implementations, the first distance may be greater than the second distance.

In some implementations, in the third direction, one word-line interconnect of the word-line interconnects may extend through a first dielectric layer and a second dielectric layer in a stack structure in the connection area to connect with a corresponding word line of the plurality of word lines. The first dielectric layer may be different from the second dielectric layer.

In some implementations, one of the memory cells may further include a storage unit. A third dielectric layer may be arranged laterally and approximately at a level, relative to the third direction, where an electrode structure of the storage unit may be connected with a corresponding semiconductor body of the semiconductor bodies.

In some implementations, the third dielectric layer may include a silicon boron nitride layer.

In some implementations, the third dielectric layer may extend across the memory array area, without extending to the connection area.

In some implementations, one memory cell of the memory cells may include a storage unit that includes an electrode structure having a first end connected with one semiconductor body of the semiconductor bodies and a second end. One word-line interconnect of the word-line interconnects may include a third end connected with the first word line and a fourth end. The second end of the electrode structure may be substantially flush with the fourth end of the word-line interconnect.

In some implementations, a surface area of the second end of the electrode structure may be substantially identical to a surface area of the fourth end of the word-line interconnect.

In some implementations, in the third direction, a length of the word-line interconnect may be greater than a length of the electrode structure.

In some implementations, the memory array area may include a first sub-memory area and a second sub-memory area. One word line of the plurality of word lines may extend, in the first direction, from the first sub-memory area to the second sub-memory area. The connection area may be arranged between the first sub-memory area and the second sub-memory area.

In some implementations, the two rows of the semiconductor bodies may include a first row of the semiconductor bodies and a second row of the semiconductor bodies. The memory device may further include an isolation structure arranged between the second row of the semiconductor bodies and a third row of the semiconductor bodies and configured to isolate the second row of the semiconductor bodies from the third row of the semiconductor bodies.

In some implementations, a first semiconductor structure may include the array of memory cells and the plurality of word lines. The memory device may further include peripheral circuits arranged in a second semiconductor structure. The first semiconductor structure may be bonded with the second semiconductor structure. The plurality of word lines in the first semiconductor structure may be electrically coupled with the peripheral circuits in the second semiconductor structure.

In certain aspects, a method for forming a memory device is provided. The method may include forming an array of memory cells in a memory array area, the memory cell including a semiconductor body; and forming a plurality of word lines extending, in a first direction, from the memory array area to a connection area. In the connection area, word-line interconnects may extend in a third direction to connect with the plurality of word lines. The third direction may be perpendicular to the first direction. The plurality of word lines may include a first word line and a second word line arranged in a second direction and between two rows of the semiconductor bodies. The second direction may be perpendicular to the first and third directions. In the second direction, a first distance between the first word line and the second word line in the connection area may be greater than a second distance between the first word line and second word line in the memory array area.

In some implementations, forming the plurality of word lines that include the first word line and the second word line, may include: forming a conductive layer between the two rows of the semiconductor bodies and connecting the two rows of the semiconductor bodies; and removing portions of the conductive layer to split the conductive layer into the first word line and the second word line. In the second direction, a first end of the first word line may be substantially flush with a second end of the second word line.

In some implementations, the method may include forming a plurality of bit lines connected with the semiconductor bodies at a first side of the semiconductor bodies; and forming the word-line interconnects in the connection area, at a second side of the semiconductor bodies opposite to the first side, extending in the third direction to connect with the plurality of word lines.

In some implementations, forming the word-line interconnects extending in the third direction to connect with the plurality of word lines, may include: forming a plurality of channel holes extending in the third direction, wherein the plurality of channel holes include a first channel hole in the memory array area and a second channel hole extending, in the third direction, through a stack structure, to reach the first word line in the connection area, a length of the second channel hole may be greater than a length of the first channel hole in the third direction; and filling the second channel hole with one or more conductive materials to be in contact with the first word line to form one word-line interconnect of the word-line interconnects.

In some implementations, the method may further include forming a first dielectric layer and a second dielectric layer over the first dielectric layer, the stack structure including the first and second dielectric layers. Forming the plurality of channel holes may include forming the second channel hole, in the connection area, extending through the second dielectric layer and the first dielectric layer to reach the first word line.

In some implementations, forming the plurality of channel holes extending in the third direction may include forming the first channel hole in the memory array area and the second channel hole in the connection area simultaneously.

In some implementations, the method may further include forming an electrode structure of a storage unit, connected with a first semiconductor body of the semiconductor bodies, corresponding to the first channel hole in the memory array area. The electrode structure of the storage unit and the word-line interconnect may be arranged at a same side of the first semiconductor body.

In some implementations, the method may further include forming a third dielectric layer in the memory array area. Forming the plurality of channel holes may include forming the first channel hole in the memory array area, extending through the stack structure and stopping at the third dielectric layer, the first channel hole corresponding to the first semiconductor body.

In some implementations, the third dielectric layer may include a silicon boron nitride layer.

In some implementations, the storage unit may include the electrode structure having a first end connected with the first semiconductor body and a second end. The word-line interconnect may include a third end connected with the first word line and a fourth end. A surface area of the second end of the electrode structure may be substantially identical to a surface area of the fourth end of the word-line interconnect.

In some implementations, in the second direction, the second end of the electrode structure may be substantially flush with the fourth end of the word-line interconnect.

In some implementations, in the third direction, a length of the word-line interconnect may be greater than a length of the electrode structure.

In some implementations, the two rows of the semiconductor bodies may include a first row of the semiconductor bodies and a second row of the semiconductor bodies. The method may further include forming an isolation structure arranged between the second row of the semiconductor bodies and a third row of the semiconductor bodies. The isolation structure may be configured to isolate the second row of the semiconductor bodies from the third row of the semiconductor bodies.

In some implementations, the method may further include forming a first semiconductor structure including the array of memory cells and the plurality of word lines; forming a second semiconductor structure including peripheral circuits; and bonding the first semiconductor structure with the second semiconductor structure, wherein the plurality of word lines in the first semiconductor structure may be electrically coupled with the peripheral circuits in the second semiconductor structure.

### BRIEF DESCRIPTION OF THE DRAWINGS

The accompanying drawings, which are incorporated herein and form part of the specification, illustrate some implementations of the present disclosure and, together with the description, further serve to explain the principles of the present disclosure and to enable a person skilled in the pertinent art to make and use the present disclosure.

FIG. 1 illustrates a schematic diagram of an exemplary memory device including peripheral circuits and an array of memory cells having vertical transistors, according to some aspects of the present disclosure.

FIG. 2A illustrates a schematic plan view of exemplary word lines in a memory device having vertical transistors, according to some aspects of the present disclosure.

FIG. 2B illustrates a schematic cross-sectional view of an exemplary word line in a memory device having vertical transistors, according to some aspects of the present disclosure.

FIG. 3 illustrates a schematic diagram of an exemplary system having one or more memory devices, according to some aspects of the present disclosure.

FIG. 4A illustrates a schematic view of a cross-section of an exemplary 3D memory device, according to some aspects of the present disclosure.

FIG. 4B illustrates a schematic view of a cross-section of another exemplary 3D memory device, according to some aspects of the present disclosure.

FIG. 5 illustrates a perspective view of an exemplary memory device implementing front-side word-line solutions, according to some aspects of the present disclosure invention.

FIG. 6 illustrates a flowchart of an exemplary method for forming individual word lines in a memory device, according to some aspects of the present disclosure.

FIGS. 7A-7D illustrate schematic plan views of a memory device during various fabrication processes for forming exemplary individual word lines, according to some aspects of the present disclosure.

FIGS. 8A-8D illustrate schematic side views showing exemplary fabrication processes from the front side of a memory device, according to some aspects of the present disclosure.

FIGS. 9A-9D illustrate schematic side views showing other exemplary fabrication processes from the backside of a memory device, according to some aspects of the present disclosure.

FIG. 10 illustrates a flowchart of an exemplary method for forming word-line interconnects in a memory device, according to some aspects of the present disclosure.

FIG. 11A illustrates a schematic cross-sectional view of a memory device during fabrication processes for forming exemplary channel holes, according to some aspects of the present disclosure.

FIG. 11B illustrates a schematic diagram of an exemplary mask for forming channel holes, according to some aspects of the present disclosure.

FIG. 12A illustrates a schematic plan view of a memory device during fabrication processes for forming exemplary word-line interconnects, according to some aspects of the present disclosure.

FIGS. 12B-12C illustrate schematic cross-sectional views of a memory device during fabrication processes for forming exemplary word-line interconnects, according to some aspects of the present disclosure.

FIG. 13A illustrates a schematic plan view of another memory device during fabrication processes for forming other exemplary word-line interconnects, according to some aspects of the present disclosure.

FIGS. 13B-13C illustrate schematic cross-sectional views of a memory device during fabrication processes for forming other exemplary word-line interconnects, according to some aspects of the present disclosure.

FIG. 14 illustrates a schematic plan view of still another memory device having word lines and word-line interconnects, according to some aspects of the present disclosure.

FIG. 15 illustrates a schematic cross-sectional view of yet another memory device having word lines and word-line interconnects, according to some aspects of the present disclosure.

Some implementations of the present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “some implementations,” “exemplary implementations,” “other implementations,” “some examples,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure, or characteristic is described in connection with an implementation, it would be within the knowledge of a person skilled in the pertinent art to effect such feature, structure, or characteristic in connection with other implementations whether or not explicitly described.

In general, terminology may be understood at least in part from usage in context. For instance, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the terms “based on” and “according to” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Furthermore, a layer can be a region of a homogeneous or inhomogeneous continuous structure that has a thickness less than the thickness of the continuous structure. For instance, a layer can be located between any pair of horizontal planes between, or at, a top surface and a bottom surface of the continuous structure. A layer can extend laterally, vertically, and/or along a tapered surface. A substrate can be a layer, can include one or more layers therein, and/or can have one or more layers thereupon, thereabove, and/or therebelow. A layer can include multiple layers. For instance, an interconnect layer can include one or more conductor and contact layers (in which interconnect lines and/or vertical interconnect access ‘VIA’ contacts are formed) and one or more dielectric layers.

As used herein, the terms “nominal/nominally” and “substantial/substantially” refer to a desired, or target, value of a characteristic or parameter for a component or a process operation, set during the design phase of a product or a process, together with a range of values above and/or below the desired value. The range of values can be due to slight variations in manufacturing processes or tolerances. As used herein, the terms “about” and “approximately” indicate the value of a given quantity that can vary based on a particular technology node associated with the subject semiconductor device. Based on the particular technology node, the terms “about” and “approximately” can indicate a value of a given quantity that varies within, for example, 10-30% of the value (e.g., ±10%, ±20%, or ±30% of the value).

As used herein, the term “three-dimensional (3D) memory device” may refer to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “memory string” may refer to a vertically-oriented string of memory cell transistors connected in series on a laterally-oriented substrate so that the string of memory cell transistors extends in the vertical direction with respect to the substrate. As used herein, the term “vertical/vertically” may refer to a direction perpendicular to the lateral surface of a substrate.

Transistors are commonly used as switches or selection devices in memory technologies such as dynamic random-access memory (DRAM), phase-change memory (PCM), and ferroelectric DRAM (FRAM). Planar transistors in conventional memory cells, however, typically have a horizontal structure, with word lines buried in the substrate and bit lines above a substrate. This lateral arrangement of the source and drain of the planar transistors increases their occupied areas. Additionally, the planar transistor design complicates the organization of interconnected structures including the arrangement of word lines and bit lines, which can limit the pitch of these lines, increasing fabrication complexity and reducing production yield.

To address these issues, vertical transistors are introduced to replace the conventional planar transistors as the switches and selecting devices in memory devices (e.g., DRAM, PCM, and FRAM). The memory cell array may include vertical transistors having a semiconductor structure extending in a vertical direction and a gate structure.

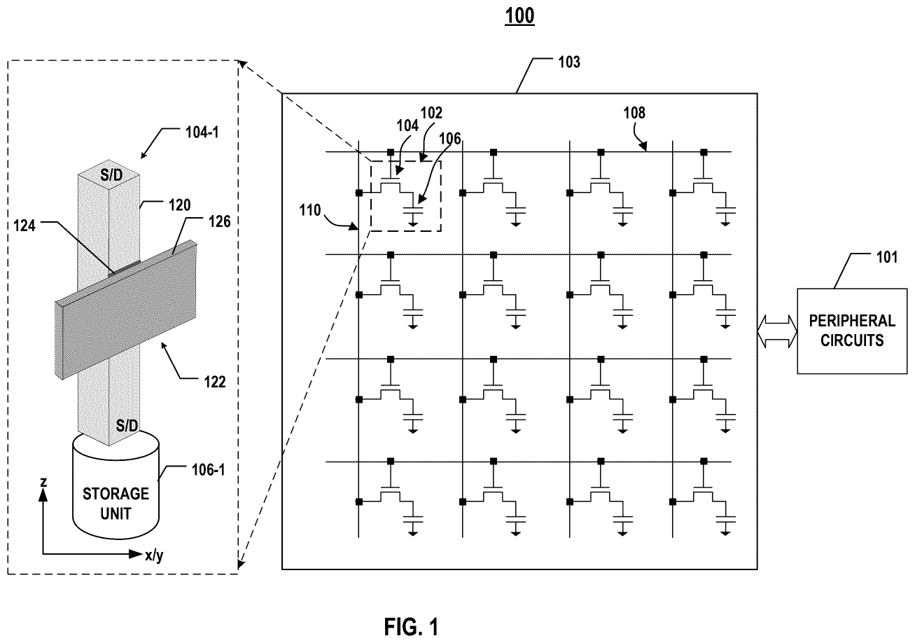

FIG. 1 illustrates a schematic diagram of an exemplary memory device 100 including peripheral circuits 101 and an array of memory cells 103 (or termed “memory cell array”) having vertical transistors 104, according to some aspects of the present disclosure. In some implementations, memory device 100 can include memory cell array 103 having memory cells 102, and memory cell 102 can include a vertical transistor 104 and a storage unit (e.g., capacitor) 106 coupled to vertical transistor 104. In some instances, memory cell array 103 can be a DRAM cell array, and the storage unit can be a capacitor 106 configured to store charges in the DRAM cell.

As shown in FIG. 1, memory cells 102 can be organized as a two-dimensional (2D) memory cell array 103 having multiple rows and multiple columns. Memory device 100 can include word lines 108 and bit lines 110. Word lines 108 can be configured to electrically couple memory cell array 103 to peripheral circuits 101 for controlling the switching of vertical transistors 104. The word line 108 may extend in a first lateral direction (i.e., the horizontal direction in FIG. 1; referred to as the word-line direction) to connect with corresponding vertical transistors 104 in a row of memory cell array 103. On the other hand, bit lines 110 can be configured to couple memory cell array 103 to peripheral circuits 101 for sending data to and/or receiving data from memory cells 102. The bit line 110 may extend in a second lateral direction (i.e., the vertical direction in FIG. 1; referred to as the bit-line direction) to connect corresponding vertical transistors 104 in a column of memory cell array 103. In some examples, a gate of the vertical transistor 104 can be connected with a corresponding word line 108. One of the source and the drain of the vertical transistor 104 can be connected with a corresponding bit line 110, and the other one of the source

As shown in the left box of FIG. 1, in some examples, vertical transistors 104-1, such as vertical metal-oxide-semiconductor field-effect transistors (MOSFETs), can replace the conventional planar transistors as the pass transistors of memory cells 102 to reduce the area occupied by the pass transistors, the coupling capacitance, as well as the interconnect routing complexity. In some implementations, different from the planar transistors in which the active regions are formed in the substrates, vertical transistor 104-1 may include a semiconductor body 120 extending vertically (in the z-direction) above a substrate (not shown) and a gate structure 122 in contact with one or more sides of semiconductor body 120. In some implementations, gate structure 122 of vertical transistor 104-1 can be in contact with one side of semiconductor body 120, as shown in FIG. 1.

Gate structure 122 can include a gate dielectric 124 over the side of semiconductor body 120. In some examples, gate structure 122 can further include a gate electrode 126 over and in contact with gate dielectric 124 at the side of gate electrode 126. Gate dielectric 124 can include any suitable dielectric materials, such as silicon oxide, silicon nitride, silicon oxynitride, or high-k dielectric materials. Gate electrode 126 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

It can be understood that gate electrode 126 and word line 108 shown in memory cell array 103 may be a continuous conductive structure in some examples. In other words, gate electrode 126 may be viewed as part of word line 108 that forms gate structure 122, or word line 108 may be viewed as an extension of gate electrode 126 to be coupled with peripheral circuits 101. It can also be understood that although semiconductor body 120 is shown as a cuboid shape in FIG. 1, semiconductor body 120 can have any suitable 3D shape, such as polyhedron shapes or cylinder shapes. The present disclosure does not limit thereto.

As shown in FIG. 1, vertical transistor 104-1 can further include a pair of a source and a drain (S/D, dope regions, a.k.a., source electrode and drain electrode) formed at the two ends of vertical transistor 104-1 in the vertical direction (the z-direction), respectively. Gate structure 122 can be formed between the source and drain. As a consequence, one channel (not shown) of vertical transistor 104-1 can be formed in semiconductor body 120 vertically between the source and drain when a gate voltage applied to gate electrode 126 of gate structure 122 can be above a threshold voltage of vertical transistor 104-1.

As shown in FIG. 1, storage unit 106-1 can be coupled with one of the source/drain of vertical transistor 104-1. In some examples, storage unit 106-1 can include any devices capable of storing binary data (e.g., 0 and 1), including but not limited to, capacitors for DRAM cells and FRAM cells, and PCM elements for PCM cells. In some implementations, vertical transistor 104-1 can control the selection and/or the state switch of the respective storage unit 106-1 coupled to vertical transistor 104-1. In some instances, vertical transistor 104-1 and storage unit 106-1 may be misaligned in the z-direction, as shown in FIG. 1, for, e.g., the convenient routing of word lines 108 to achieve a more compact size of memory device 100. In certain instances, however, vertical transistor 104-1 and storage unit 106-1 can be aligned in the z-direction. The present disclosure does not limit thereto.

Peripheral circuits 101 can be coupled with memory cell array 103 through bit lines 110, word lines 108, and any other suitable conductive wirings. Peripheral circuits 101 (or termed “control and sensing circuits”) can include any suitable digital, analog, and/or mixed-signal circuits used for facilitating the operations of the memory cell array by applying and sensing voltage signals and/or current signals through word lines 108 and bit lines 110 to and from memory cell 102. For instance, peripheral circuits 101 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuits 101 can use complementary metal-oxide-semiconductor (CMOS) technology, e.g., which can be implemented with logic processes (e.g., various technology nodes), according to some implementations.

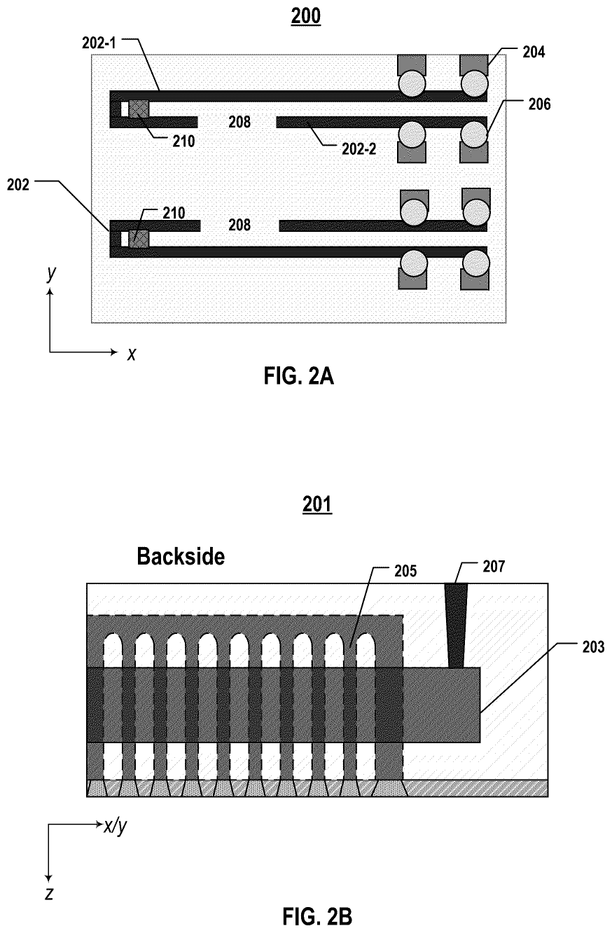

FIG. 2A illustrates a schematic plan view of exemplary word lines 202 in a memory device 200 having vertical transistors 204, according to some aspects of the present disclosure. FIG. 2B illustrates a schematic cross-sectional view of exemplary word line 203 in a memory device 201 having vertical transistors 205, according to some aspects of the present disclosure. Memory devices 200 and 201 can be a 3D memory device. FIG. 2A provides a partial plan view of 3D memory device 200, while FIG. 2B provides a partial cross-sectional view of 3D memory device 201. FIG. 2B can be a cross-sectional view along a word line, such as word line 202 in FIG. 2A. It should be noted that certain components (such as vertical transistors 205) are depicted in FIG. 2B, but they may not lie directly on the cross-section. These components may be at varying distances relative to word line 203. Their inclusion in the cross-sectional view is merely intended to illustrate the spatial relationship between these components and word line 203 for explanatory purposes.

In some implementations as shown in FIG. 2A, vertical transistors 204 can be arranged in an array form, and storage units 206 can be formed each corresponding to a vertical transistor 204. In some implementations, vertical transistor 204 can include a semiconductor body and a gate structure located at one side of the semiconductor body, as shown in FIG. 1. The gate structure of vertical transistors 204 in a row of the memory cell array (i.e., the x-direction or the word-line direction) can be electrically coupled, thereby extending to form a word line 202. In some instances, multiple gate structures of the row in the memory cell array can be connected, e.g., by a continuous conductive layer, and the conductive layer can extend in the word-line direction (i.e., the x-direction in FIG. 2A), thereby forming word line 202 corresponding to the row of vertical transistors 204.

In the fabrication processes, a continuous conductive layer can be formed corresponding to two rows of vertical transistors 204 in the memory cell array. In some implementations, a conductive layer can be formed. Part of the conductive layer can then be removed (e.g., forming a cut 208), and the conductive layer can be separated into a pair of individual word lines 202-1 and 202-2, as shown in FIG. 2A. Word lines 202-1 and 202-2 can independently control one row of vertical transistors 204. Accordingly, memory device 200 can include multiple word lines 202, extending along the first lateral direction. Subsequently, a word-line interconnect 210 can be formed corresponding to the word line 202, which enables electrical connectivity between word lines 202 and peripheral circuits 101, facilitating signal transmission across memory device 200.

To form the word-line interconnects that connect to the word lines, in some implementations, memory device 201 having word line 203 that connects a row of vertical transistors 205, as shown in FIG. 2B, can be flipped over to access its backside. A hole can then be created from the backside of memory device 201, extending down to reach a corresponding word line 203. Conductive material, such as tungsten, can then be deposited into the hole, thereby forming word-line interconnect 207, as shown in FIG. 2B.

These processes, however, impose significant limitations on the routing direction of word lines 203. Due to confining word lines 203 to specific paths, the overall design flexibility is reduced, making it difficult to optimize the layout for the performance or density of memory device 201. Additionally, this backside approach also places further constraints on how the semiconductor structure having the memory cell array can bond with another semiconductor structure. The reliance on the backside processes for word-line pickup complicates the integration of wiring and bonding, adding complexity to the fabrication processes. As demands for higher density and performance continue to grow, these limitations could lead to increased fabrication challenges and potentially hinder advancements in semiconductor technology.

To address one or more of the aforementioned issues, the present disclosure offers solutions where the continuous conductive layer in a memory cell array can be separated using a mask. Through the layout of the mask, the conductive material of parts of the conductive layer can be removed, and dielectric material(s) can then be filled in, thereby forming a pair of individual word lines for controlling corresponding rows of vertical transistors. Moreover, channel holes existing in a connection region can be utilized, thereby functioning as word-line interconnects. For instance, these channel holes can be formed vertically (i.e., in the z-direction) extending down to be in contact with respective word lines from the front side of a semiconductor structure having the word lines. This approach of leading the word lines out from the front side introduces more flexibility as it can streamline the locating processes and minimize the need for the formation of additional holes at the backside.

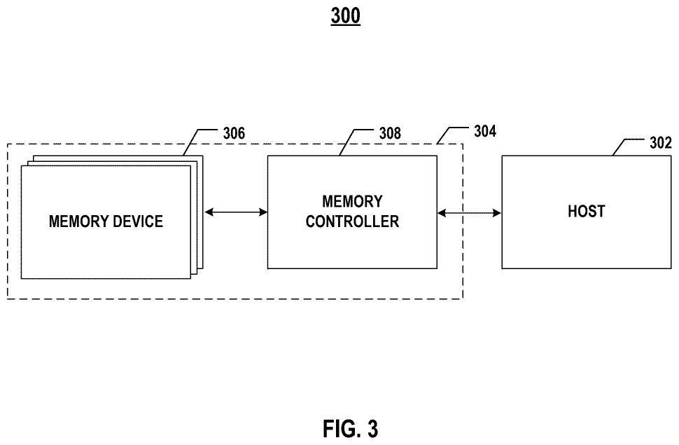

FIG. 3 illustrates a schematic diagram of an exemplary system 300 having one or more memory devices 306, according to some aspects of the present disclosure. System 300 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 3, system 300 can include a host 302 and a memory system 304 having one or more memory devices 306 and a memory controller 308. Host 302 can be a processor of an electronic device, such as a central processing unit (CPU), or a system-on-chip (SoC), such as an application processor (AP). Host 302 can be configured to send or receive the data to or from memory device 306.

Memory device 306 can be any memory devices disclosed in the present disclosure, such as 3D memory devices (e.g., DRAM, PCM, FRAM). In some implementations, memory device 306 can include an array of memory cells including a vertical transistor, and can further implement front-side word-line solutions, as described below in detail.

Memory controller 308 can be coupled to memory device 306 and host 302 and may be configured to control memory device 306, according to some implementations. Memory controller 308 can manage the data stored in memory device 306 and communicate with host 302. Memory controller 308 can be configured to control operations of memory device 306, such as read, write, and refresh operations. Memory controller 308 can also be configured to manage various functions with respect to the data stored or to be stored in memory device 306 including, but not limited to refresh and timing control, command/request translation, buffer and schedule, and power management.

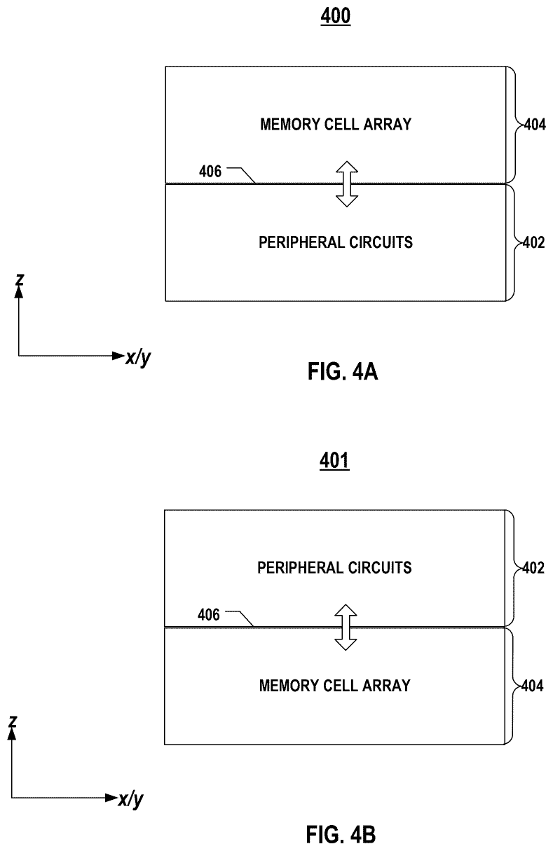

FIG. 4A illustrates a schematic view of a cross-section of an exemplary 3D memory device 400, according to some aspects of the present disclosure. 3D memory device 400 may represent an example of a bonded chip. The components of 3D memory device 400 (e.g., memory cell array and peripheral circuits) can be formed separately on different substrates and then combined to form a bonded chip. 3D memory device 400 can include a first semiconductor structure 402 that includes peripheral circuits of a memory cell array. In some implementations, 3D memory device 400 can also include a second semiconductor structure 404 that includes the memory cell array. In some implementations, second semiconductor structure 404 can include an array of memory cells that can use vertical transistors as the switch and selecting devices. In some implementations, the memory cell array may include an array of DRAM cells. For ease of description, in certain instances, DRAM cell array can be used as an example for describing the memory cell array in the present disclosure.

Second semiconductor structure 404 can be a DRAM device in which memory cells are provided in the form of an array of DRAM cells. In some implementations, the DRAM cell can include a capacitor for storing a bit of data as a positive or negative electrical charge as well as one or more vertical transistors that control access to the capacitor. In some examples, the DRAM cell can include one transistor and one capacitor and have a 1T1C structure.

As shown in FIGS. 4A, 3D memory device 400 further includes a bonding interface 406 vertically between (in the vertical direction, e.g., the z-direction in FIG. 4A) first semiconductor structure 402 and second semiconductor structure 404. In some implementations, first and second semiconductor structures 402 and 404 can be fabricated separately (and in parallel with some implementations) such that the thermal budget for fabricating one of first and second semiconductor structures 402 and 404 does not limit the processes of fabricating another one of first and second semiconductor structures 402 and 404. Moreover, multiple interconnects (e.g., bonding contacts) can be formed through bonding interface 406 to make direct, short-distance (e.g., micron-level) electrical connections between first semiconductor structure 402 and second semiconductor structure 404, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in second semiconductor structure 404 and the peripheral circuits in first semiconductor structure 402 can be performed through the interconnects (e.g., bonding contacts) across bonding interface 406. By vertically integrating first and second semiconductor structures 402 and 404, the chip size can be reduced, and the memory cell density can be increased.

It can be understood that the relative positions of stacked first and second semiconductor structures 402 and 404 are not limited. Therefore, FIG. 4B illustrates a schematic view of a cross-section of another exemplary 3D memory device 401, according to some implementations. Different from 3D memory device 400 in FIG. 4A in which second semiconductor structure 404 including the memory cell array is above first semiconductor structure 402 including the peripheral circuits, in 3D memory device 401 in FIG. 4B, first semiconductor structure 402 including the peripheral circuits is above second semiconductor structure 404 including the memory cell array. Bonding interface 406 is formed vertically between first and second semiconductor structures 402 and 404 in 3D memory device 401, and first and second semiconductor structures 402 and 404 are combined vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously.

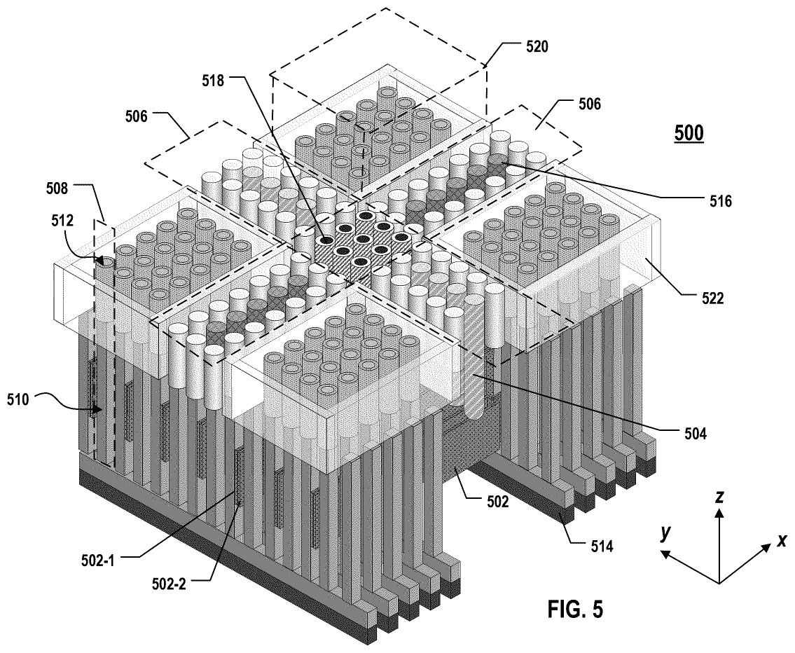

FIG. 5 illustrates a perspective view of an exemplary memory device 500 implementing front-side word-line solutions, according to some aspects of the present disclosure invention. The front-side word-line solutions provide approaches to pick up/route word lines from the front side of a semiconductor structure to enable electrical connection between the word lines and the peripheral circuits. In the present disclosure, the terms “word-line pickup” and “word-line routing” are used to refer to certain processes of locating word lines and forming word-line interconnects (e.g., in a connection area) to be in direct contact with the word lines for an electrical connection.

It is noted that the x, y, and z axes are included in FIG. 5 to further illustrate the spatial relationship of the components in memory device 500. The substrate (not shown) of memory device 500 may include two lateral surfaces extending laterally in the x-y plane: a top surface on the front side of the wafer on which semiconductor devices are formed, and a bottom surface on the backside opposite to the front side of the wafer. The z-axis is perpendicular to both the x and y axes.

As used herein, whether one component (e.g., a layer or a device) is “on,” “above,” or “below” another component (e.g., a layer or a device) of the 3D memory device can be determined relative to the substrate of the 3D memory device in the z-direction (the vertical direction perpendicular to the x-y plane, e.g., the thickness direction of the substrate) when the substrate is positioned in the lowest plane of the 3D memory device in the z-direction. Accordingly, in the present disclosure, the term “front-side” is used to refer to the side facing the positive-z direction in FIG. 5, while the term “backside” refers to the opposite side, oriented in the negative-z direction. The same notion for describing spatial relationships is applied throughout the present disclosure. Further, in the description of the present disclosure, the term “depth” may be used to indicate a distance or length from the top or bottom surface of one reference item (e.g., a substrate) along the z-direction.

As shown in FIG. 5, memory device 500 may include a plurality of memory cells 508. In some implementations, memory cells 508 can be organized as a 2D array having multiple rows and multiple columns. The memory cell 508 in the array can include a vertical transistor 510 and a storage unit 512 stacked relative to the z-direction. In some implementations, memory device 500 can further include word lines 502 and bit lines 514. The word line 502 may extend in the first lateral direction (i.e., the x-direction or the word-line direction), and the bit line 514 may extend in the second lateral direction (i.e., the y-direction or the bit-line direction). Bit lines 514 can be configured to electrically couple the memory cell array having memory cells 508, through bit-line interconnects 516, to the peripheral circuits. In some implementations, bit-line interconnects 516 can be formed using channel holes in a connection area 506.

In some implementations of the present disclosure, two word lines 502 can be formed by removing parts of one conductive layer, thereby turning the conductive layer into two independent conductive wires. Through splitting the conductive layer in the y-direction, the end of a word line 502-1 can substantially flush with the end of another word line 502-2 in the x-direction, as shown in FIG. 5. The distances in the y-direction, between the pair of adjacent word lines that are formed from the same conductive layer, can be different in connection area 506 and a memory area. Details will be provided in the following descriptions.

Consistent with the scope of the present disclosure, word-line interconnects 504 can be formed utilizing channel holes created in connection area 506 by extending the depth of the channel holes in the z-direction until reaching word lines 502. Subsequently, the channel holes can be filled with conductive material(s), thereby forming word-line interconnects 504 that connect word lines 502, as shown in FIG. 5. As a consequence, word lines 502 can electrically couple vertical transistors 510, through word-line interconnects 504, to the peripheral circuits.

In some implementations, memory device 500 can further include one or more through silicon contacts (TSCs) 518 in connection area 506. TSC 518, also known as a through-silicon via, is a vertical electrical connection used in 3D memory devices for integration. TSCs enhance signal integrity by minimizing interferences. In some implementations, memory cells 508 in the memory array area can be further organized into multiple sub-memory areas 520, as shown in FIG. 5. In some instances, memory cells 508 in one sub-memory area 520 can be circumscribed by an isolation wall 522, but the present disclosure does not limit thereto. In some implementations, word lines 502 can extend laterally (in the x-direction) from one sub-memory area 520 to another sub-memory area 520. In some implementations, connection area 506 can be arranged between two adjacent sub-memory areas 520.

In some implementations, the word line 502 may extend in the x-direction, and the bit line 514 may extend in the y-direction. Accordingly, in connection area 506, word-line interconnects 504 can be arranged in the y-direction to pick up word lines 502 arranged in the x-direction. In some implementations, in connection area 506, bit-line interconnects 516 can be arranged in the x-direction to pick up bit lines 514 arranged in the y-direction. In some implementations, TSCs can be formed in the intersection of word-line interconnects 504 and bit-line interconnects 516.

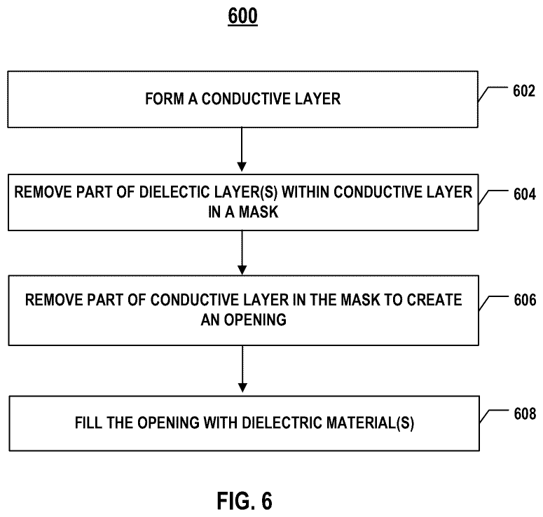

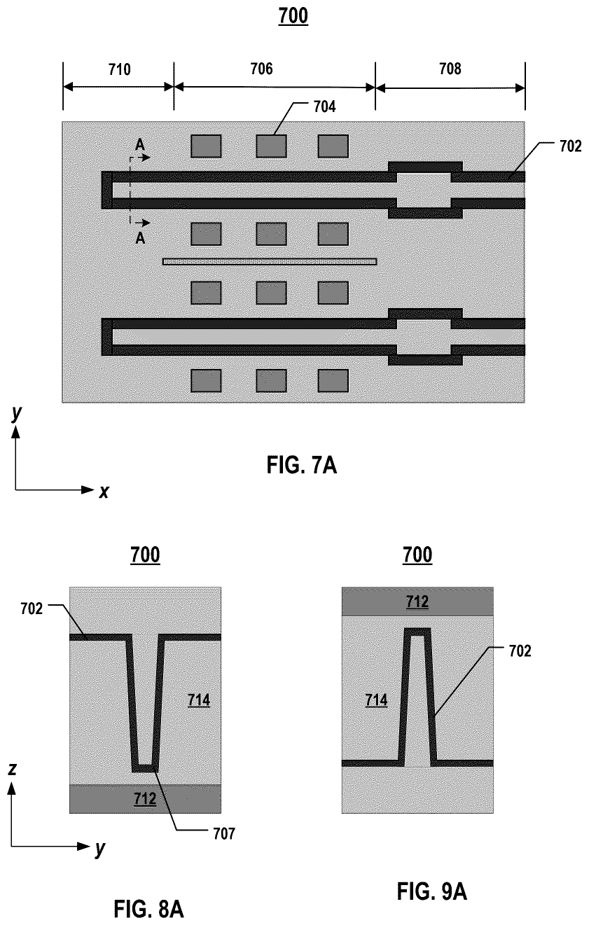

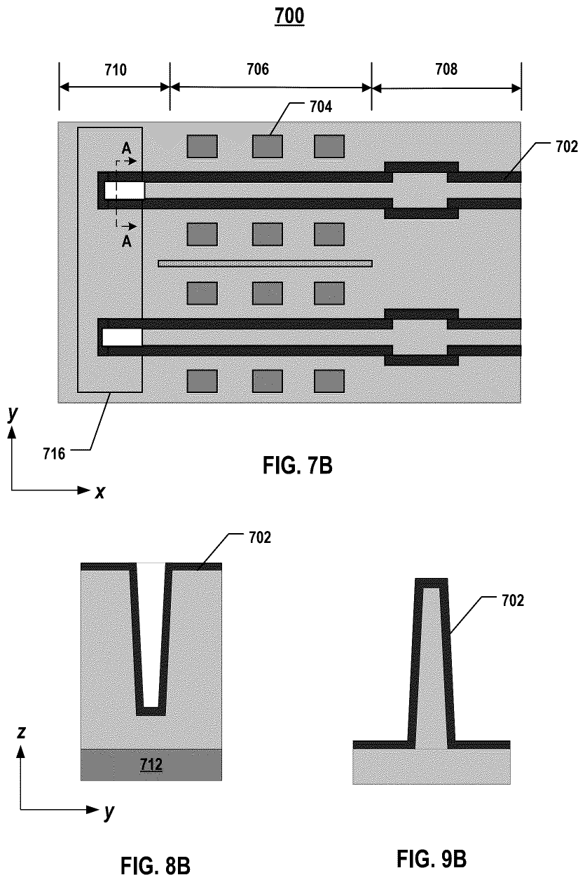

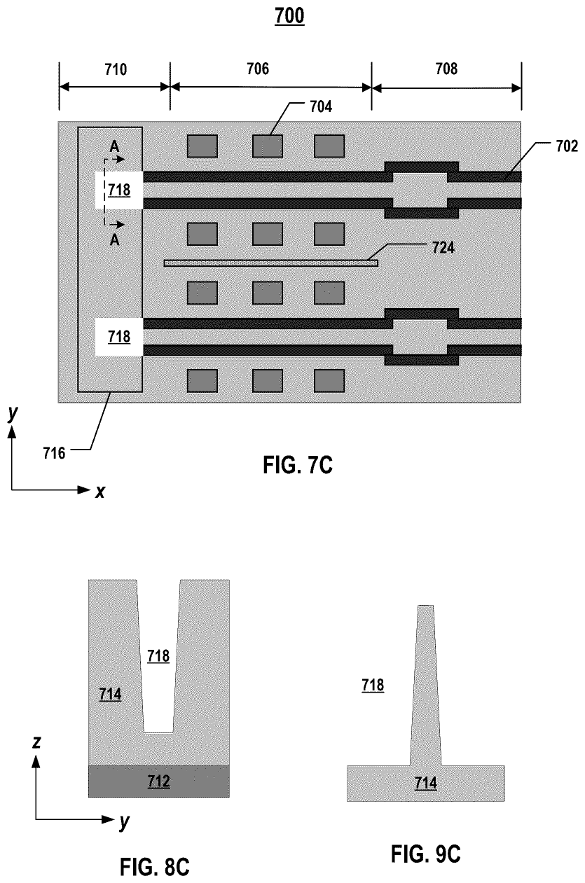

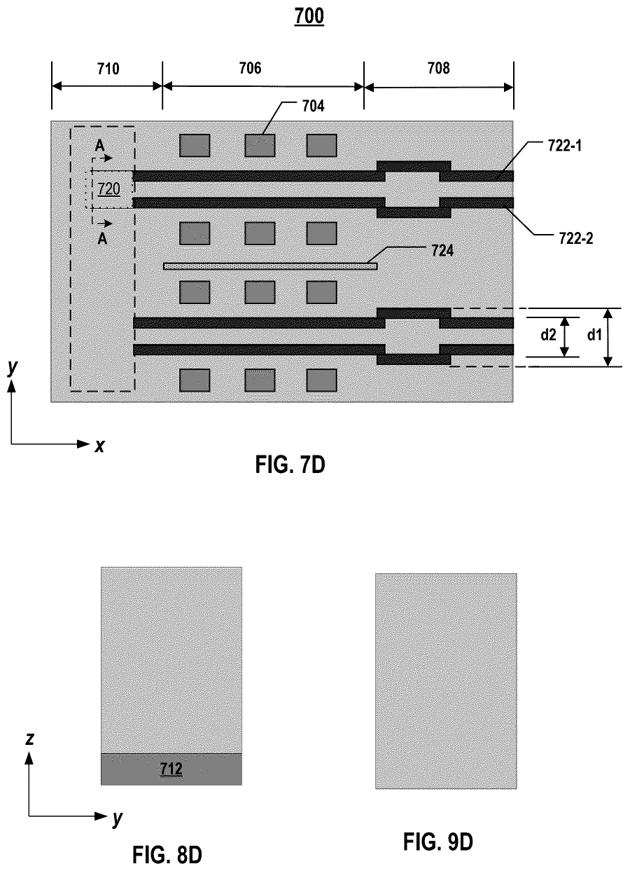

FIG. 6 illustrates a flowchart of an exemplary method 600 for forming individual word lines in a memory device, according to some aspects of the present disclosure. FIGS. 7A-7D illustrate schematic plan views of a memory device 700 during various fabrication processes for forming exemplary individual word lines, according to some aspects of the present disclosure. FIGS. 8A-8D illustrate schematic side views showing exemplary fabrication processes from the front side of a memory device. FIGS. 9A-9D illustrate schematic side views showing other exemplary fabrication processes from the backside of a memory device.

To form individual word lines in a memory device, method 600 can start at operation 602. At operation 602, a plurality of conductive layers 702 can be formed in a semiconductor structure of memory device 700, as shown in FIG. 7A. In some implementations, conductive layers 702 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some examples, conductive layers 702 may include tungsten (W).

In some implementations, the conductive layer 702 formed in memory device 700 can correspond to two rows of vertical transistors 704. For instance, as shown in FIG. 7A, the conductive layer 702 may be arranged between the two rows of vertical transistors 704. The rectangular box with reference numeral 704 in FIGS. 7A-7C can represent a semiconductor body (e.g., semiconductor body 120 in FIG. 1) of one vertical transistor. In some instances, the conductive layer 702 can be arranged between the two rows of semiconductor bodies of vertical transistors 704. In some examples, the conductive layer 702 can be formed in a looped configuration from a plan view. In the present disclosure, the term “looped” is used to describe a continuous and uninterrupted path of conductive layer 702 that forms a closed configuration. The choice of a looped conductive layer may be an option to facilitate the fabrication processes, although the present disclosure is not limited thereto. In other implementations, from a plan view, conductive layer 702 may be continuous in memory array area 706 and connection area 708, but be discontinuous in separation area 710. By removing the discontinuous portion of conductive layer 702 in separation area 710 with other suitable processes, two independent word lines can be formed.

In some implementations, the conductive layer 702 can extend in the lateral direction (i.e., the x-direction; the word-line direction) across memory device 700. In some examples, the conductive layer 702 can extend from a memory array area 706 to a connection area 708, in the x-direction. Part of the conductive layer 702 (e.g., a corner portion of conductive layer 702) may be arranged in a separation area 710 adjacent to memory array area 706. In some implementations, the configuration of conductive layer 702 in connection area 708 can be different from that in memory array area 706, as shown in FIG. 7A. Details will be described below.

FIG. 8A provides a cross-sectional view (e.g., along a sectional line A-A) of a memory device (e.g., memory device 700) for describing subsequent front-side word-line solutions, while FIG. 9A presents a flipped perspective of memory device 700 by showing a substrate 712 on the top for introducing fabrication processes of two individual word lines from the backside. In certain implementations consistent with the core of the present disclosure, substrate 712 can be prepared first, and a dielectric layer(s) 714 (e.g., including a silicon oxide layer) can then be deposited over substrate 712. Within dielectric layer(s) 714, vertical transistors 704 having a semiconductor body and a gate structure, and continuous/looped conductive layers 702 connecting two rows of the gate structures in memory array area 706 can be formed. In some implementations, the conductive layer 702 can be arranged between the two rows of semiconductor bodies of vertical transistors 704 in memory array area 706.

Method 600 may proceed to operations 604 and 606, where a mask 716 may be applied to remove unwanted portions in separation area 710. In some implementations, the width of mask 716 in the x-direction can be approximately 100 nm, and the corner parts of conductive layers 702 in separation area 710 can be covered within mask 716, as shown in FIG. 7B. Based on mask 716, sequentially, part of dielectric layer(s) 714 can be removed at operation 604, and part of the conductive layer 702 can be removed at operation 606, as shown in FIGS. 7B and 7C. In some examples, at operations 604 and 606, portions of the conductive layer 702 and dielectric layer(s) 714 can be removed using wet etching and/or dry etching, such as DRIE. For instance, one or more etchants can be applied onto dielectric layer(s) 714 and conductive layer 702. The etchant can include any suitable etchants that can etch dielectric layer(s) 714 selective to conductive layer 702. Accordingly, dielectric layer(s) 714 within conductive layer 702 in mask 716 can be selectively removed. Subsequently, conductive layer 702 in mask 716 can then be removed, thereby forming an opening 718.

In some implementations, the removal processes can be performed from the front side of the semiconductor structure opposite to substrate 712, as shown in FIGS. 8B and 8C. Accordingly, substrate 712 can be retained at the bottom, as shown in FIGS. 8B and 8C. In other implementations, the removal processes may be performed (e.g., applying etchant(s) onto substrate 712) from the back side of the semiconductor structure. As a consequence, substrate 712 can also be removed with the part of dielectric layer(s) 714, as shown in FIGS. 9B and 9C. The present disclosure does not limit thereto.

Method 600 may proceed to operation 608, where a dielectric layer 720 can be filled into opening 718, as shown in FIGS. 7D, 8D, and 9D. In some implementations, dielectric layer 720 can be identical to dielectric layer(s) 714. For example, each of first and second dielectric layers 714 and 720 can include a silicon oxide layer, while in other examples, they may be different.

Consistent with the core of the present disclosure, conductive layer 702 can include the first portion, extending in the x-direction, corresponding to the first row of semiconductor bodies of the vertical transistors and the second portion, extending in the x-direction, corresponding to the second row of semiconductor bodies of the vertical transistors. In some implementations, conductive layer 702 may further include the third portion that is a bottom layer 707 that connects the first portion and the second portion, as shown in FIG. 8A. Bottom layer 707 may extend laterally across memory array area 706 in dielectric layer(s) 714. In some implementations, bottom layer 707 of the conductive layer 702 can be completely removed before or after the storage units are formed, on which the present disclosure does not place a limitation. For instance, from the back side, a certain thickness of a semiconductor structure, including a substrate and bottom layer 707, can be removed after storage units are formed. Consequently, two individual and adjacent word lines 722-1 and 722-2, from the same conductive layer, can be formed.

In some implementations, word lines 722-1 and 722-2 can be arranged between the two rows of semiconductor bodies of vertical transistors 704. In certain examples, in the second lateral direction (i.e., the y-direction; the bit-line direction), the first distance d1, between first word line 722-1 and second word line 722-2 in connection area 708 can be greater than the second distance d2 between first word line 722-1 and second word line 722-2 in memory array area 706, as shown in FIG. 7D. In some implementations, the second distance d2 may change abruptly to the first distance d1 in connection area 708, as shown in FIG. 7D. However, in other implementations, the transition can occur gradually, with a slope or a smooth curve where the second distance d2 slowly changes to the first distance d1. The present disclosure does not limit thereto.

For ease of illustration, in FIGS. 7A-7D, 8A-8D, and 9A-9D, only certain components are depicted. It can be understood that memory device 700 can include other components, such as an isolation structure 724 configured to isolate (e.g. electrically) two rows of vertical transistors 704. By placing isolation structure 724 between the memory cells (e.g., between semiconductor bodies of vertical transistors), it can be assured that vertical transistors remain electrically isolated, maintaining the integrity of the switching operations. In some implementations, other suitable components can be included in these figures. The present disclosure does not limit thereto. Based on memory device 700 having independent word lines 722, word-line interconnects can be formed accordingly.

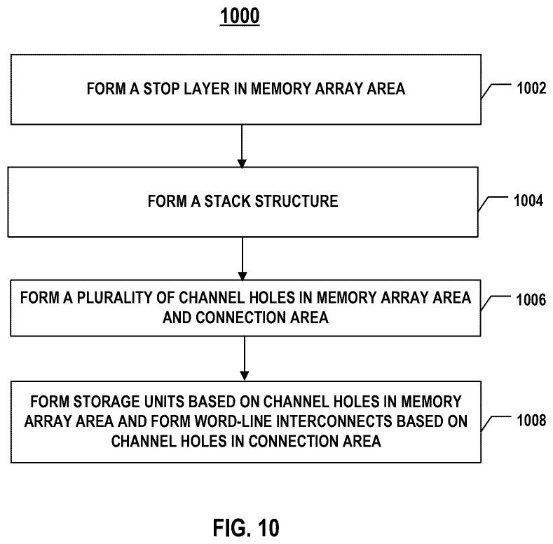

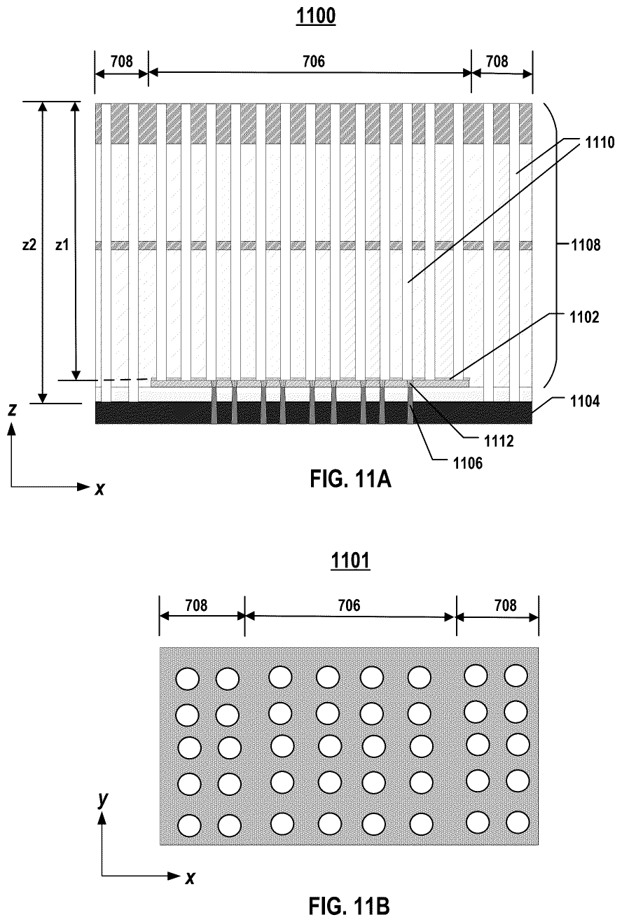

FIG. 10 illustrates a flowchart of an exemplary method 1000 for forming word-line interconnects in a memory device, according to some aspects of the present disclosure. FIG. 11A illustrates a schematic cross-sectional view of a memory device 1100 during fabrication processes for forming exemplary channel holes, according to some aspects of the present disclosure. Memory device 1100 can be an example of memory device 700, and word line 1104 can be formed by the approaches described in regard to FIG. 6.

Method 1000 starts at operation 1002. At operation 1002, a stop layer 1102 can be formed over a transistor structure in memory array area 706. In some instances, the formation of stop layer 1102 can be constrained within memory array area 706 of memory device 1100. In some implementations, stop layer 1102 can extend across memory array area 706 laterally, without extending to connection area 708. In some implementations, stop layer 1102 can cover a portion of connection area 708, leaving another portion of connection area 708 uncovered. In some implementations, stop layer 1102 may extend across memory array area 706 as well as connection area 708. The present disclosure does not limit thereto, once stop layer 1102 can cover memory array area 706.

In some implementations, stop layer 1102 can include a dielectric layer. For example, stop layer 1102 can include at least one of a silicon boron nitride layer or a silicon nitride layer. In some implementations, stop layer 1102 can extend across memory array area 706 laterally, without extending to connection area 708. In the subsequent fabrication processes, stop layer 1102 can function as a stop layer to prevent channel holes in memory array area 706 from penetrating various layers below stop layer 1102. Consequently, the channel hole formed later in memory array area 706 can have a smaller length (or depth) z1 in the z-direction, compared to the length (or depth) z2 of a channel hole in connection area 708 where stop layer 1102 is absent.

Method 1000 may proceed to operation 1004. At operation 1004, a stack structure 1108 can be formed in connection area 708 and memory array area 706, as shown in FIG. 11A. In some implementations, stack structure 1108 can include a plurality of dielectric layers, including the first dielectric layer and the second dielectric layer. In some examples, stack structure 1108 can include a silicon nitride layer, a silicon carbon nitride layer, and/or a silicon oxide layer. For instance, stack structure 1108 can include a first silicon oxide layer, a silicon carbon nitride layer stacked over the first silicon oxide layer, a second silicon oxide layer stacked over the silicon carbon nitride layer, and a silicon nitride layer stacked over the second silicon oxide layer. In some implementations, stack structure 1108 can laterally extend across memory array area 706 and connection area 708. In some implementations, in subsequent fabrication processes, stack structure 1108 in memory array area 706 may be removed, while in connection area 708, stack structure 1108 can be retained. For instance, one or more layers of stack structure 1108 of memory array area 706 can be sequentially removed using wet etching and/or dry etching, such as DRIE. In some implementations, stack structure 1108 can be completely removed in memory array area 706 in subsequence processes so as to form components of storage units, e.g., capacitor dielectrics and electrode structures.

Method 1000 may proceed to operation 1006. At operation 1006, a plurality of channel holes 1110 can be formed in memory array area 706 and connection area 708, as shown in FIG. 11A. In some implementations, a mask 1101 (e.g., a hard mask), as shown in FIG. 11B, covering both memory array area 706 and connection area 708 of memory device 1100 can be formed over stack structure 1108. In some examples, mask 1101 can include polysilicon and/or silicon oxide. Mask 1101 can include multiple uncovered portions, the uncovered portion being configured to form one channel hole 1110 in memory array area 706 or one channel hole 1110 in connection area 708. In some examples, the uncovered portion of mask 1101 can include a circle, and areas of these circles can be identical. As such, the surface areas of ends of the channel holes can be identical.

At operation 1006, part of stack structure 1108 can be removed, for example, from the top of memory device 1100 using mask 1101. In some implementations, to form the channel hole, stack structure 1108 can be patterned using lithography followed by wet etching and/or dry etching. As a consequence, portions of stack structure 1108 (e.g., portions of the first dielectric layer and the second dielectric layer), both in memory array area 706 and connection area 708, corresponding to channel holes can be removed. Subsequently, mask 1101 can be removed from stack structure 1108. In some implementations, stop layer 1102 can function as a stop layer to prevent the removal processes in memory array area 706 from proceeding further once stop layer 1102 is encountered. In other words, the removal processes in memory array area 706 are halted by the presence of stop layer 1102.

In some implementations, stop layer 1102 can be formed to extend across memory array area 706 as well as connection area 708. Accordingly, channel holes 1110 in memory array area 706 and connection area 708 can be initially created to stop at stop layer 1102 to have the same length. Subsequently, stop layer 1102 and other layers in channel holes 1110 of connection area 708 can be further removed. As a result, the channel hole 1110 in connection area 708 can have a greater length than a channel hole 1110 in memory array area 706.

In some implementations, after stop layer 1102 is reached, stop layer 1102 inside the channel hole 1110 can be further removed to ensure that the channel hole exposes a respective vertical transistor 1106 below. In some examples, a source node contact (SNC) structure 1112 of vertical transistor 1106 can be exposed in channel holes 1110 of memory array area 706. In some implementations, stop layer 1102 may include the third dielectric layer, and the third dielectric layer inside the channel hole 1110 in memory array area 706 can be removed. In some implementations, SNC structures 1112 can be configured to couple vertical transistors 1106 with storage units formed later in channel holes 1110 in memory array area 706. For instance, subsequently, channel holes in memory array area 706 can be filled with a conductive material(s) to form electrode structures of storage units. The electrode structures of storage units can be configured to have electrical connection with SNC structures 1112 of vertical transistors 1106. The SNC structure 1112 can be arranged on top of the semiconductor body of a respective vertical transistor 1106 and include a conductive layer in contact with a corresponding electrode structure formed later. In some implementations, SNC structures 1112 can be arranged in an array form and disposed in one or more dielectric layers below stop layer 1102.

Consequently, in the z-direction, the length (or depth) z1 of the channel hole 1110 in memory array area 706 can be smaller than the length (or depth) z2 of the channel hole 1110 in connection area 708 where stop layer 1102 is absent, as shown in FIG. 11A. In some implementations, the channel hole 1110 in connection area 708 can include a sufficient length/depth in the z-direction such that word line 1104 is reached. In some implementations, a portion of channel holes in connection area 708 can be configured to form bit-line interconnects in connection area 708. The bit-line interconnects can be configured to couple bit lines with bit-line contacts formed later.

In some implementations, channel holes 1110 for forming storage units in memory array area 706 and channel holes 1110 for forming word-line interconnects in connection area 708 may be created simultaneously. In some implementations, channel holes 1110 for forming storage units in memory array area 706, channel holes 1110 for forming word-line interconnects in connection area 708, and channel holes 1110 for forming bit-line interconnects in connection area 708 can be created simultaneously. In some implementations, the size of the circle in mask 1101 may be identical. Consequently, as shown in FIG. 11A, at the side away from word line 1104, the surface area of the end of one channel hole 1110 for forming a storage unit in memory array area 706 can be the same as the surface area of the end of another channel hole 1110 for forming a word-line interconnect in connection area 708.

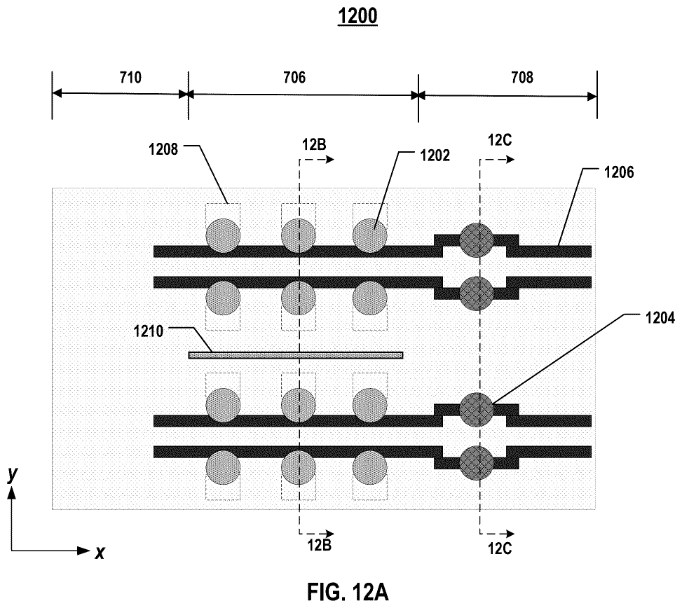

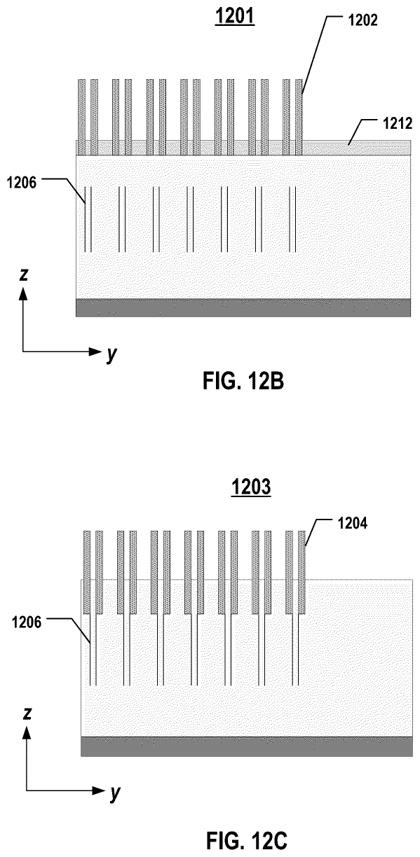

FIG. 12A illustrates a schematic plan view of a memory device 1200 during fabrication processes for forming exemplary word-line interconnects, according to some aspects of the present disclosure. Method 1000 may proceed to operation 1008, where storage units 1202 in FIG. 12A can be formed based on channel holes 1110 in memory array area 706, and word-line interconnects 1204 can be formed based on channel holes 1110 in connection area 708.

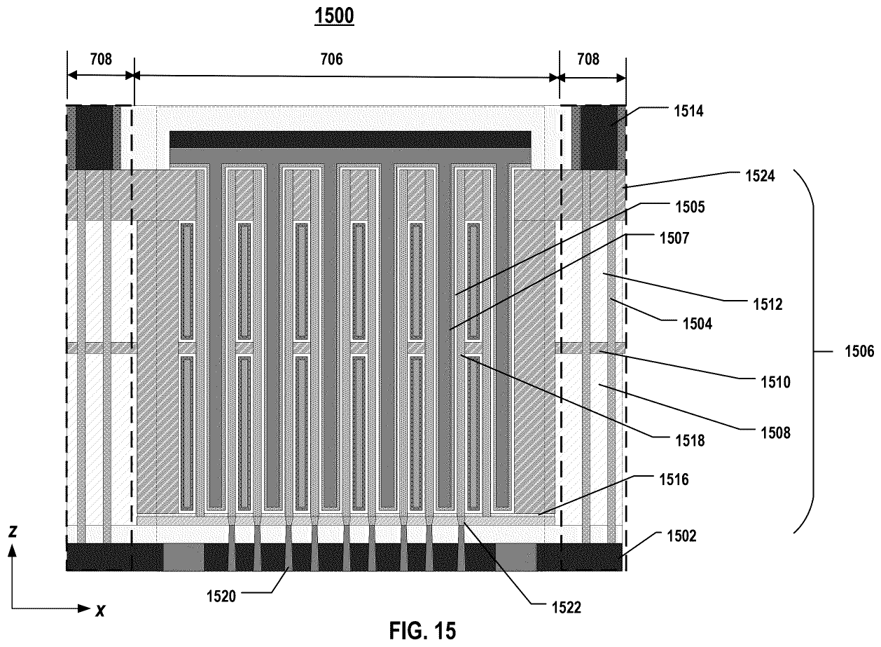

In some implementations, storage units 1202 can include capacitors. For instance, in channel holes 1110 in memory array area 706 in FIG. 11A, electrode structures of the capacitors (e.g., a first electrode structure 1518 in FIG. 15) can be formed. The electrode structure can be one electrode of storage units 1202 that couples to a respective semiconductor body. In some implementations, the electrode structures may be formed by depositing one or more conductive layers into channel holes 1110 in memory array area 706 (in FIG. 11A) using one or more thin film deposition processes such as CVD, PVD, ALD, or any combination thereof. For instance, the electrode structures can be formed by filling channel holes 1110 in memory array area 706 with titanium nitride (TiN). The electrode structure as formed can be configured to be in direct contact with SNC structure 1112 in FIG. 11A to couple storage unit 1202 with the source of a respective vertical transistor. Subsequently, the other electrode and capacitor dielectrics can be formed to function as a capacitor in contact with semiconductor bodies of the vertical transistors.

In some implementations, storage units 1202 can be formed on the opposite side of bit lines (shown in FIG. 5) with respect to the semiconductor bodies of the vertical transistors. In some examples, a bit line may be coupled to the drain of the vertical transistor, while storage unit 1202 may be coupled to the source of the vertical transistor. In some implementations, memory device 1200 may include a separation area 710 where a conductive layer is split to form two individual word lines 1206 subsequently, as shown in FIG. 12A. Separation area 710 may be arranged at the border of memory array area 706. It can be understood that, in the present disclosure, the division of separation area 710 from memory array area 706 can be made for ease of description. In some descriptions, separation area 710 can be viewed as part of memory array area 706 or connection area 708.

In some implementations, at operation 1008, word-line interconnects 1204 can be formed based on channel holes 1110 in connection area 708. For instance, channel holes 1110 in connection area 708 can have greater depths than channel holes 1110 in memory array area 706 until word lines 1104 are encountered. One or more conductive materials can be deposited into channel holes 1110 in connection area 708, thereby forming word-line interconnect 1204, as shown in FIG. 12A. The one or more conductive materials may include metal (e.g., Tungsten) or metal compounds, using one or more thin film deposition processes including, but not limited to, CVD, PVD, ALD, or any combination thereof to fill the portion of channel holes 1110 in connection area 708. In some implementations, the planarization processes (e.g., chemical mechanical planarization, CMP) may be performed to remove residual materials after forming word-line interconnects 1204, such that the top surface of word-line interconnects 1204 may be substantially flush with the top surface of storage units 1202. In some implementations, the formation of word-line interconnects 1204 in connection area 708 and the formation of electrode structures of storage units 1202 in memory array area 706 can be performed simultaneously. In some implementations, the formation of word-line interconnects 1204 in connection area 708, the formation of electrode structures of storage units 1202 in memory array area 706, and the formation of bit-line contacts in connection area 708 can be performed simultaneously.

In some implementations, memory device 1200 may include an isolation structure 1210, and isolation structure 1210 can be configured to isolate (e.g., electrically) two rows of memory cells. For instance, isolation structure 1210 may be configured to arrange between two rows of semiconductor bodies of the vertical transistors to isolate (e.g., electrically) these vertical transistors. Vertical transistors are part of signal paths and are sensitive to interference. In some cases, electrical noise or interference between adjacent vertical transistors can cause unwanted switching, leakage, or faulty operations, which could corrupt the stored data in storage units 1202. By placing isolation structure 1210 between the memory cells (e.g., between vertical transistors), it can be assured that vertical transistors remain electrically isolated, maintaining the integrity of the switching operations.

FIGS. 12B-12C illustrates schematic cross-sectional views of memory device 1200 during fabrication processes for forming exemplary word-line interconnects 1204, according to some aspects of the present disclosure. FIG. 12B shows a sectional view 1201 along a sectional line 12B-12B in FIG. 12A, and sectional view 1201 can represent a sectional view in memory array area 706. Memory device 1200 may include storage units 1202 and word lines 1206, as shown in sectional view 1201 of FIG. 12B. As shown in FIG. 12B, word lines 1206 and storage units 1202 are not in contact and not electrically coupled in memory array area 706. In some implementations, to reach this goal, the length of channel holes corresponding to storage units 1202 can be controlled. For instance, as shown in FIG. 12B, a stop layer 1212 can be arranged to control the channel hole in memory array area 706 not to exceed a certain length. In some implementations, stop layer 1212 can be arranged laterally and approximately at the level, relative to the z-direction, where storage units 1202 are connected with semiconductor bodies of the vertical transistors.

On the other hand, FIG. 12C shows a sectional view 1203 along a sectional line 12C-12C in FIG. 12A. Sectional view 1203 can represent a sectional view in connection area 708. Memory device 1200 may include word-line interconnects 1204 and word lines 1206, as shown in sectional view 1203 of FIG. 12C. In FIG. 12C, word-line interconnects 1204 and word lines 1206 can be electrically connected in connection area 708. In some implementations, for this purpose, stop layer 1212 in memory array area 706 of FIG. 12B can be controlled not to extend to connection area 708 in FIG. 12C. As such, the channel hole corresponding to a word-line interconnect 1204 may have a greater length (depth in the z-direction) than the length of a channel hole corresponding to storage units 1202 in memory array area 706. As shown in FIG. 12A, in some implementations, two word-line interconnects 1204 can be aligned in sectional line 12C-12C. Consequently, in sectional view 1203 in FIG. 12C, two word-line interconnects 1204 can be connected to two word lines 1206, respectively, although the present disclosure does not limit thereto. In some implementations, in connection area 708 along one word line 1206, more than one word-line interconnects 1204 can be arranged, for example, two or four word-line interconnects 1204 corresponding to one word line 1206 in a connection area 708.

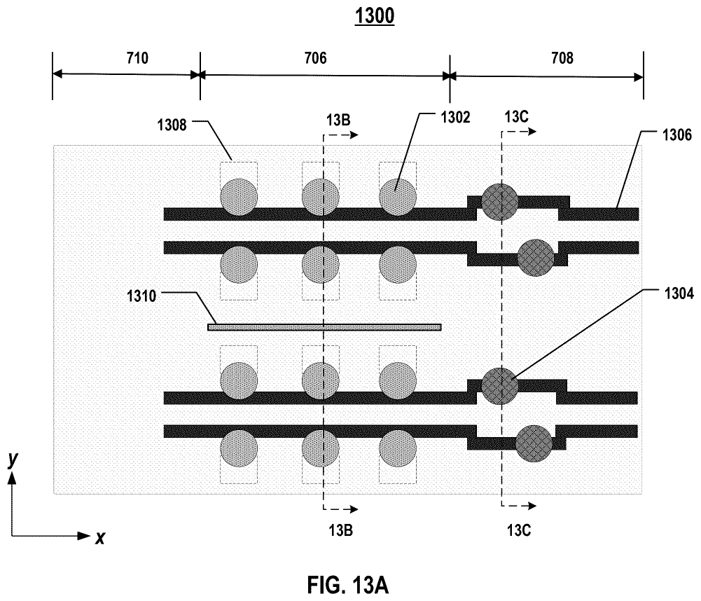

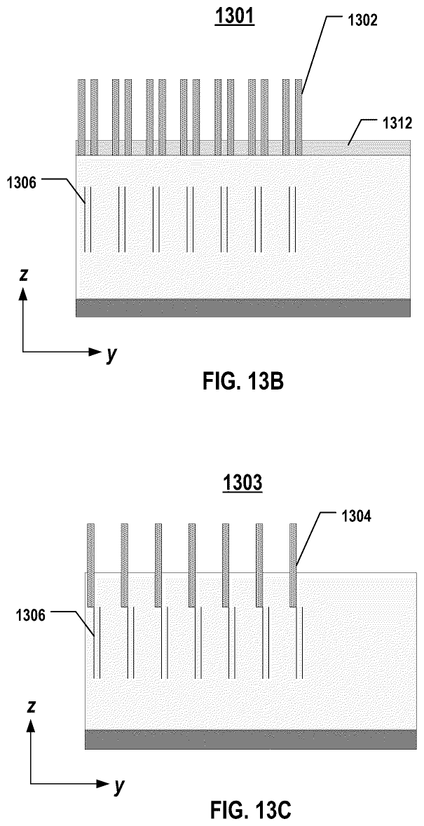

FIG. 13A illustrates a schematic plan view of another memory device 1300 during fabrication processes for forming other exemplary word-line interconnects 1304, according to some aspects of the present disclosure. In some implementations, memory device 1300 may include word-line interconnects 1304 misaligned in sectional line 13C-13C, as shown in FIG. 13A. In some implementations, in memory array area 706, memory device 1300 may have the same (or similar) configurations as those in FIG. 12B. Accordingly, memory device 1300 may include storage units 1302 and word lines 1306, as shown in sectional view 1301 of FIG. 13B. As shown in FIG. 13B, word lines 1306 and storage units 1302 are not in contact in memory array area 706. In some implementations, stop layer 1312 can be arranged laterally and approximately at the level, relative to the z-direction, where storage units 1302 are connected with semiconductor bodies of the vertical transistors.

On the other hand, as shown in a sectional view 1303 of FIG. 13C, memory device 1200 may include word-line interconnects 1304 and word lines 1306. In some implementations, word-line interconnects 1304 and word lines 1306 can be electrically connected in connection area 708. Due to the misalignment of two word-line interconnects 1304, only one word-line interconnect 1304, connected to word line 1306, is depicted, as shown in FIG. 13C.

In some implementations, memory device 1300 may include an isolation structure 1310, and isolation structure 1310 can be configured to electrically isolate two rows of memory cells. For instance, isolation structure 1310 may be configured to arrange between two rows of semiconductor bodies of the vertical transistors to electrically isolate these vertical transistors.

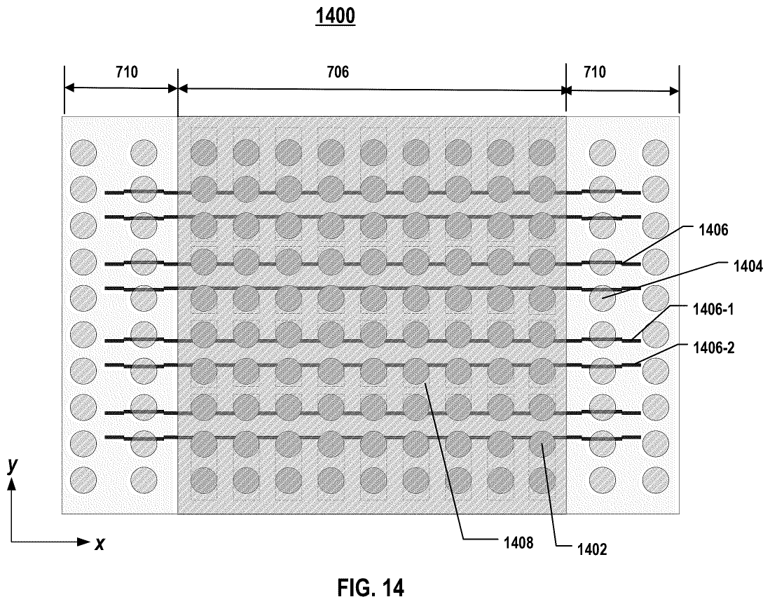

FIG. 14 illustrates a schematic plan view of still another memory device 1400 having word lines 1406 and word-line interconnects 1404, according to some aspects of the present disclosure. For ease of illustration, FIG. 14 only shows two separation areas 710 and one memory array area 706 between the two separation areas 710. In some implementations, word-line interconnects 1404 can be formed to extend in the z-direction to electrically connect with word lines 1406. Word lines 1406 can be formed to connect with semiconductor bodies of vertical transistors 1408, and storage units 1402 can be formed corresponding to vertical transistors 1408. In some implementations, two adjacent word lines can be formed from splitting a conductive layer by removing the corner portions of the conductive layer, in separation area 710, as shown in FIG. 14. In some implementations, the first word line 1406-1 and the second word line 1406-2 can be arranged between two rows of semiconductor bodies of vertical transistors 1408. In some examples, the end of the first word line 1406-1 is substantially flush with the end of the second word line 1406-2, as shown in FIG. 14.

FIG. 15 illustrates a schematic cross-sectional view of yet another memory device 1500 having word lines 1502 and word-line interconnects 1504, according to some aspects of the present disclosure. FIG. 15 can represent a cross-section view along a word line 1502. In some implementations, word-line interconnects 1504 may be formed to extend, through a stack structure 1506, in the z-direction, thereby connecting to word lines 1502, as shown in FIG. 15. In some implementations, stack structure 1506 can include a plurality of dielectric layers, including a silicon nitride layer, a silicon carbon nitride layer, and/or a silicon oxide layer. In some examples, stack structure 1506 can include a first silicon oxide layer 1508, a silicon carbon nitride layer 1510 stacked over first silicon oxide layer 1508, a second silicon oxide layer 1512 stacked over silicon carbon nitride layer 1510, and a silicon nitride/silicon carbon nitride layer 1524 stacked over second silicon oxide layer 1512.

In some implementations, memory device 1500 may include a stop layer 1516 laterally extending across memory array area 706, without extending to connection area 708, as shown in FIG. 15. In the fabrication processes, the channel hole, corresponding to a respective storage unit (e.g., a first electrode structure 1518 of a storage unit), can be stopped before stop layer 1516 and have a length smaller than the length of a channel hole corresponding to word-line interconnect 1504. Subsequently, first electrode structure 1518 can be formed in the channel holes of memory array area 706 over semiconductor bodies 1520 of vertical transistors, as shown in FIG. 15. In some implementations, first electrode structure 1518 can be arranged to be in contact with SNC structure 1522 of a respective vertical transistor, as shown in FIG. 15. In some implementations, memory device 1500 may further include a second electrode structure 1507 and dielectrics 1505 between first electrode structure 1518 and second electrode structure 1507, thereby forming a capacitor that functions as a storage unit.

It should be noted that certain components (such as semiconductor bodies 1520) are depicted in FIG. 15, but they may not lie directly on the cross-section. These components may be at varying distances relative to word line 1502. Their inclusion in the cross-sectional view is merely intended to illustrate the spatial relationship between these components and word line 1502 for explanatory purposes.

In some examples, second electrode structure 1507 can include one or more conductive layers (e.g., a Titanium Nitride layer). In some implementations, dielectrics 1505 can include a dielectric material(s), such as silicon oxide, silicon nitride, or high-k dielectrics including, but not limited to, aluminum oxide (Al2O3), hafnium oxide (HfO2), tantalum oxide (Ta2O5), zirconium oxide (ZrO2), titanium oxide (TiO2), or any combination thereof. In some implementations, one or more conductive layers and one or more dielectric layers can be arranged over the storage units.

In some implementations, at the side away from word line 1502, the surface area of the end of the part of the storage unit (e.g., first electrode structure 1518) in memory array area 706 can be the same as the surface area of the end of a word-line interconnect 1504 in connection area 708.

In some implementations, memory device 1500 may include one or more interlayer dielectric (ILD) layers incorporating various local contacts (such as bit line contacts) in contact with the memory cells of the 1T1C structure. The local contacts may include conductive materials including, but not limited to, W, Co, Cu, Al, silicides, or any combination thereof. The ILD layers can include dielectric materials including, but not limited to, silicon oxide, silicon nitride, silicon oxynitride, low-k dielectrics, or any combination thereof.

In some implementations, memory device 1500 may include word-line contacts 1514, and word-line contacts 1514 may be formed corresponding to word-line interconnects 1504 and configured to route/pick up word lines 1502 to connect with peripheral circuits. In some implementations, memory device 1500 may include bit lines and bit-line contacts configured to route/pick up the bit lines to connect with the peripheral circuits.

In some implementations, memory device 1500 can be formed in the first semiconductor structure, and the peripheral circuits can be formed in the second semiconductor structure, individually or independently. Subsequently, the first semiconductor structure can be bonded with the second semiconductor structure, e.g., according to the manners of FIG. 4A or FIG. 4B, so that the memory device 1500 in the first semiconductor structure can be electrically connected to the peripheral circuits in the second semiconductor structure, through word-line contacts 1514, word-line interconnects 1504, the bit lines, the bit-line contacts, etc. As such, by means of, e.g., applying various voltages on word lines 1502 and the bit lines through the peripheral circuits, memory device 1500 can be controlled by a memory controller (e.g., memory controller 308 in FIG. 3).

Accordingly, the present disclosure offers various solutions where individual word lines can be formed from conductive layers, and word-line interconnects can be formed from channel holes in a connection area. According to the core of the present disclosure, the word-line interconnects can be formed from the front side of a memory device. The approach of leading the word lines out from the front side introduces more flexibility as it can streamline the locating process and minimize the need for the formation of additional holes at the backside.

The foregoing description of the specific implementations will reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary implementations of the present disclosure as contemplated by the inventor(s), and thus, are not intended to limit the present disclosure and the appended claims in any way.

The breadth and scope of the present disclosure should not be limited by any of the above-described exemplary implementations, but should be defined only in accordance with the following claims and their equivalents.

What is claimed is:

1. A memory device, comprising:
an array of memory cells in a memory array area, each memory cell comprising a semiconductor body; and
a plurality of word lines extending, in a first direction, from the memory array area to a connection area,
wherein:
in the connection area, word-line interconnects extend in a third direction to connect with the plurality of word lines, the third direction being perpendicular to the first direction;
the plurality of word lines comprise a first word line and a second word line arranged in a second direction and between two rows of the semiconductor bodies, the second direction being perpendicular to the first and third directions; and
in the second direction, a first distance between the first word line and the second word line in the connection area is greater than a second distance between the first word line and second word line in the memory array area.

2. The memory device of claim 1, wherein:
in the third direction, one word-line interconnect of the word-line interconnects extends through a first dielectric layer and a second dielectric layer of a stack structure in the connection area to connect with a corresponding word line of the plurality of word lines, the first dielectric layer being different from the second dielectric layer.

3. The memory device of claim 1, wherein:
one of the memory cells further comprises a storage unit; and
a third dielectric layer is arranged laterally and approximately at a level, relative to the third direction, where an electrode structure of the storage unit is connected with a corresponding semiconductor body of the semiconductor bodies.

4. The memory device of claim 1, wherein:
one memory cell of the array of memory cells comprises a storage unit that comprises an electrode structure having a first end connected with one semiconductor body of the semiconductor bodies and a second end;
one word-line interconnect of the word-line interconnects comprises a third end connected with the first word line and a fourth end; and
the second end of the electrode structure is substantially flush with the fourth end of the word-line interconnect.

5. The memory device of claim 1, wherein:
the memory array area comprises a first sub-memory area and a second sub-memory area; and
one word line of the plurality of word lines extends, in the first direction, from the first sub-memory area to the second sub-memory area, the connection area being arranged between the first sub-memory area and the second sub-memory area.

6. The memory device of claim 1, wherein:
the two rows of the semiconductor bodies comprise a first row of the semiconductor bodies and a second row of the semiconductor bodies; and
the memory device further comprises an isolation structure arranged between the second row of the semiconductor bodies and a third row of the semiconductor bodies and configured to isolate the second row of the semiconductor bodies from the third row of the semiconductor bodies.

7. The memory device of claim 1, wherein:
in the second direction, a first end of the first word line is substantially flush with a second end of the second word line.

8. The memory device of claim 1, wherein:
a first semiconductor structure comprises the array of memory cells and the plurality of word lines; and
the memory device further comprises peripheral circuits arranged in a second semiconductor structure,
wherein:
the first semiconductor structure is bonded with the second semiconductor structure; and
the plurality of word lines in the first semiconductor structure are electrically coupled with the peripheral circuits of the second semiconductor structure.

9. A memory device, comprising:
an array of memory cells in a memory array area, each memory cell comprising a semiconductor body; and
a plurality of word lines extending, in a first direction, from the memory array area to a connection area,
wherein:
in the connection area, word-line interconnects extend in a third direction to connect with the plurality of word lines, the third direction being perpendicular to the first direction;
the plurality of word lines comprise a first word line and a second word line arranged in a second direction and between two rows of the semiconductor bodies, the second direction being perpendicular to the first and third directions; and
in the second direction, a first distance between the first word line and the second word line in the connection area is different from a second distance between the first word line and second word line in the memory array area, a first end of the first word line being substantially flush with a second end of the second word line in the second direction.

10. The memory device of claim 9, wherein:
the first distance is greater than the second distance.

11. The memory device of claim 9, wherein:
in the third direction, one word-line interconnect of the word-line interconnects extends through a first dielectric layer and a second dielectric layer in a stack structure in the connection area to connect with a corresponding word line of the plurality of word lines, the first dielectric layer being different from the second dielectric layer.

12. The memory device of claim 9, wherein:
one of the memory cells further comprises a storage unit; and
a third dielectric layer is arranged laterally and approximately at a level, relative to the third direction, where an electrode structure of the storage unit is connected with a corresponding semiconductor body of the semiconductor bodies.

13. A method for forming a memory device, comprising:
forming an array of memory cells in a memory array area, each memory cell comprising a semiconductor body; and
forming a plurality of word lines extending, in a first direction, from the memory array area to a connection area,
wherein:
in the connection area, word-line interconnects extend in a third direction to connect with the plurality of word lines, the third direction being perpendicular to the first direction;
the plurality of word lines comprise a first word line and a second word line arranged in a second direction and between two rows of the semiconductor bodies, the second direction being perpendicular to the first and third directions; and
in the second direction, a first distance between the first word line and the second word line in the connection area is greater than a second distance between the first word line and second word line in the memory array area.

14. The method of claim 13, wherein forming the plurality of word lines that comprise the first word line and the second word line, comprises:
forming a conductive layer between the two rows of the semiconductor bodies and connecting the two rows of the semiconductor bodies; and
removing portions of the conductive layer to split the conductive layer into the first word line and the second word line, wherein in the second direction, a first end of the first word line is substantially flush with a second end of the second word line.

15. The method of claim 13, further comprising:
forming a plurality of bit lines connected with the semiconductor bodies at a first side of the semiconductor bodies; and
forming the word-line interconnects in the connection area, at a second side of the semiconductor bodies opposite to the first side, extending in the third direction to connect with the plurality of word lines.

16. The method of claim 13, wherein forming the word-line interconnects extending in the third direction to connect with the plurality of word lines, comprises:
forming a plurality of channel holes extending in the third direction, wherein the plurality of channel holes comprise a first channel hole in the memory array area and a second channel hole extending, in the third direction, through a stack structure, to reach the first word line in the connection area, a length of the second channel hole is greater than a length of the first channel hole in the third direction; and
filling the second channel hole with one or more conductive materials to be in contact with the first word line to form one word-line interconnect of the word-line interconnects.

17. The method of claim 16, further comprising:
forming a first dielectric layer and a second dielectric layer over the first dielectric layer, the stack structure comprising the first and second dielectric layers, wherein:
forming the plurality of channel holes comprises forming the second channel hole, in the connection area, extending through the second dielectric layer and the first dielectric layer to reach the first word line.

18. The method of claim 16, further comprises:
forming an electrode structure of a storage unit, connected with a first semiconductor body of the semiconductor bodies, corresponding to the first channel hole in the memory array area, the electrode structure of the storage unit and the word-line interconnect being arranged at a same side of the first semiconductor body.

19. The method of claim 18, further comprising:
forming a third dielectric layer in the memory array area,
wherein:
forming the plurality of channel holes comprises forming the first channel hole in the memory array area, extending through the stack structure and stopping at the third dielectric layer, the first channel hole corresponding to the first semiconductor body.

20. The method of claim 18, wherein:
the storage unit comprises the electrode structure having a first end connected with the first semiconductor body and a second end;
the word-line interconnect comprises a third end connected with the first word line and a fourth end; and
a surface area of the second end of the electrode structure is substantially identical to a surface area of the fourth end of the word-line interconnect.
